(19) United States
(12) Patent Application Publication
(10) Pub. No.: US 2008/0142908 A1
(43) Pub. Date: Jun. 19, 2008

(54) METHOD OF USING III-V SEMICONDUCTOR MATERIAL AS GATE ELECTRODE

(75) Inventors: Chih-Hung Tseng, Taipei (TW); Hsien-Ta Wu, Taipei (TW); Cheng-Yi Peng, Taipei (TW); Chee-Wee Liu, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 11/877,812

(22) Filed: Oct. 24, 2007

(30) Foreign Application Priority Data
Dec. 14, 2006 (TW) 095146950

(51) Int. Cl. H01L 29/78; H01L 21/3205

(52) U.S. Cl. 257/407; 438/590; 257/E21.294; 257/E29.255

(57) ABSTRACT

A method of using an III-V semiconductor material as a gate electrode is provided. The method includes steps of providing a substrate; forming a gate dielectric layer on the substrate; and forming the III-V semiconductor material on the gate dielectric layer.

### FIELD OF THE INVENTION

The present invention relates to a method of using the semiconductor material as the gate electrode, and more particularly to a method of using the III-V semiconductor material as the gate electrode.

### BACKGROUND OF THE INVENTION

In the conventional fabrication processes for the MOSFETs, the gate leakage current will be rapidly increased when trying to decrease physical thickness of the SiO₂ oxidation layer. Therefore, more and more documents show that the issue of the gate leakage current can be overcome and the gate capacitance can be enhanced by using the gate dielectric layer with a high dielectric constant (high-k dielectric). However, the material of the dielectric layer with a high dielectric constant is harder to be integrated with the conventional poly-crystalline silicon gate electrode. Hence, the method of using the metal as the gate electrode has been proposed. Nevertheless, due to the limitation of the threshold voltage required for the element operation, for a P-channel MOSFET, the work function of its gate electrode needs to be close to the silicon valence band. However, for an N-channel MOSFET, the work function of its gate electrode needs to be close to the silicon conduction band. Due to the above, the metals which can meet the requirement are less. Besides, a single type of metal gate that can be applied to both the P-channel and the N-channel MOSFETs is still under research.

The work function of the III-V semiconductor material can be appropriately close to the silicon valence band or the silicon conduction band. For example, the electron affinity of InAs is 4.9 eV, and after being doped as P⁺-type, the work function thereof can be adjusted to about 5.2 eV, which can meet the requirement of being close to the silicon valence band. Nevertheless, the electron affinity of GaAs is 4.07 eV, and after being doped as N⁺-type, the work function thereof can meet the requirement of being close to the silicon conduction band. In addition, the material with a wide band gap, e.g. GaP, may become a single type of gate electrode that can be applied to both the P-channel and the N-channel MOSFETs by doping it as P⁺-type or N⁺-type.

A novel field effect transistor and the manufacturing method therefor is disclosed in the Taiwan Patent No. 1234283 by Robert Zhao. The mentioned patent discloses a novel MOSFET using the semiconductor film with a narrow band gap to form the channel region. The material of the semiconductor film with a narrow band gap includes a part of the III-V semiconductor materials, such as InSb, InAs, etc. The mentioned patent proposes that the semiconductor material with a narrow band gap has high channel mobility and saturation velocity, which enables a large driving current for the transistor during low voltage operation.

The present invention proposes using the III-V semiconductor material as the gate electrode. Since the III-V semiconductor has high mobility, the resistance thereof is lower, which is suitable to serve as the gate electrode. Through doping the III-V semiconductor material as P⁺-type or N⁺-type and adjusting the doping concentration thereof, the work function thereof can be changed, which meets the requirement of the transistor fabrication processes. Besides, an appropriate threshold voltage can be obtained, thereby enhancing the performance of the field effect transistor.

In order to overcome the drawbacks in the prior art, an improved method of using the III-V semiconductor material as the gate electrode is provided. The particular design in the present invention not only solves the problems described above, but also is easy to be implemented. Thus, the present invention has the utility for the industry.

### SUMMARY OF THE INVENTION

In accordance with one aspect of the present invention, a method of using the III-V semiconductor material as the gate electrode is provided in order to adjust the threshold voltage. The III-V semiconductor material is formed on the gate dielectric layer. The work function of the III-V semiconductor material can be changed by doping it as P⁺-type or N⁺-type and changing the doping concentration thereof arbitrarily. Hence, the threshold voltage thereof can be optimized, thereby enhancing the performance of the filed effect transistor.

In accordance with another aspect of the present invention, a method of using an III-V semiconductor material as a gate electrode is provided. The method includes steps of providing a substrate; forming a gate dielectric layer on the substrate; and forming the III-V semiconductor material on the gate dielectric layer.

Preferably, the substrate is a silicon substrate.

Preferably, the silicon substrate is one of a silicon {100} substrate, a silicon {110} substrate and a silicon {111} substrate.

Preferably, the silicon substrate is doped as one of a P-type substrate and an N-type substrate.

Preferably, the silicon substrate is one of a wafer and a die.

Preferably, a size and a shape of the silicon substrate are changeable.

Preferably, the gate dielectric layer is made of a dielectric layer material with a dielectric constant larger than 3.

Preferably, the dielectric layer material is selected from a group consisting of an SiO₂, an Si₃N₄ and an HfO₂.

Preferably, the III-V semiconductor material is formed by one selected from a group consisting of a molecular beam epitaxy, a plasma-enhanced chemical vapor deposition and a chemical vapor deposition.

Preferably, the III-V semiconductor material is one selected from a group consisting of a poly-crystalline material, a single-crystalline material and an amorphous material.

Preferably, the III-V semiconductor material is a compound composed of at least one of an Al, a Ga and an In in Group III of a periodic table and at least one of an N, a P, an As and an Sb in Group V of the periodic table.

Preferably, the compound is one selected from a group consisting of an InAs, an Inp, a GaSb, a GaAs, a Gap, a GaN, an AlxGal-xAs and a GaxInl-xAs.

Preferably, the III-V semiconductor material is doped as one of a P-type material and an N-type material.

Preferably, a doping concentration of the III-V semiconductor material is adjustable.

In accordance with a further aspect of the present invention, a gate electrode is provided. The gate electrode includes an III-V semiconductor material.

Preferably, the III-V semiconductor material is formed by one selected from a group consisting of a molecular beam epitaxy, a plasma-enhanced chemical vapor deposition and a chemical vapor deposition.

Preferably, the III-V semiconductor material is one selected from a group consisting of a poly-crystalline material, a single-crystalline material and an amorphous material.

Preferably, the III-V semiconductor material is a compound composed of at least one of an Al, a Ga and an In in Group III of a periodic table and at least one of an N, a P, an As and an Sb in Group V of the periodic table.

Preferably, the compound is one selected from a group consisting of an InAs, an Inp, a GaSb, a GaAs, a Gap, a GaN, an AlxGal-xAs and a GaxInl-xAs.

Preferably, the III-V semiconductor material is doped as one of a P-type material and an N-type material.

Preferably, a doping concentration of the III-V semiconductor material is adjustable.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a schematic diagram showing the method of using the III-V semiconductor material as the gate electrode in the present invention;

FIGS. 2(a)-2(d) are schematic diagrams showing the method of using the III-V semiconductor material as the gate electrode according to a preferred embodiment of the present invention; and

FIG. 3 is a diagram showing the capacitance-voltage characteristic according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

In a metal-oxide-semiconductor capacitor, the flat-band voltage can be modulated by changing the work function of the metal. Therefore, for a MOSFET, the magnitude of the threshold voltage thereof will be affected by the magnitude of the work function of the gate electrode thereof.

A method of using the III-V semiconductor material as the gate electrode is provided in the present invention. Through doping the III-V semiconductor material as P-type or N-type and changing the doping concentration thereof arbitrarily, the work function thereof can be appropriately close to the silicon valence band or the silicon conduction band. In addition, the material with a wide band gap, e.g. GaP, may become a single type of gate electrode that can be applied to both the P-channel and the N-channel MOSFETs by doping it as P-type or N-type.

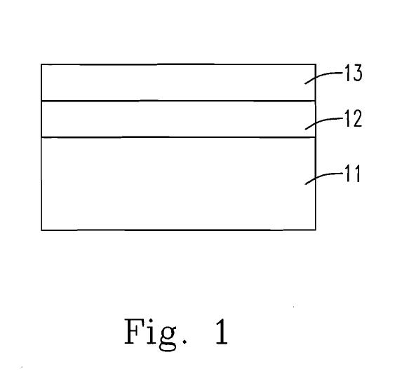

Please refer to FIG. 1, which is a schematic diagram showing the method of using the III-V semiconductor material as the gate electrode in the present invention. Firstly, a silicon substrate 11 is provided. Then, a gate dielectric layer 12 is formed on the silicon substrate 11. Finally, an III-V semiconductor material 13 is formed on the gate dielectric layer 12. As shown in FIG. 1, in the present invention, the III-V semiconductor material 13 is formed on the gate dielectric layer 12 to serve as the gate electrode. Since the III-V semiconductor has high mobility, the resistance thereof is lower, which is suitable to serve as the gate electrode. The work function of the gate can be modulated by using such novel gate electrode. Through doping the III-V semiconductor material as P-type or N-type and adjusting the doping concentration thereof, the work function thereof can be changed, which meets the requirement of the transistor fabrication processes. Besides, an appropriate threshold voltage can be obtained, thereby enhancing the performance of the field effect transistor.

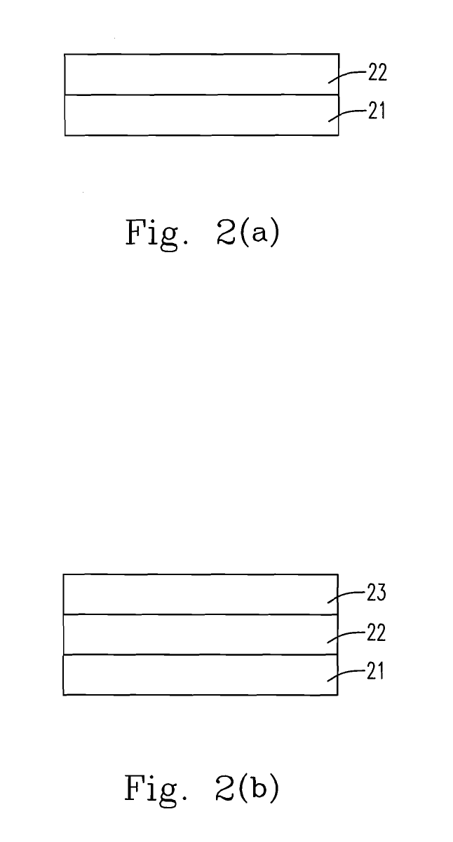

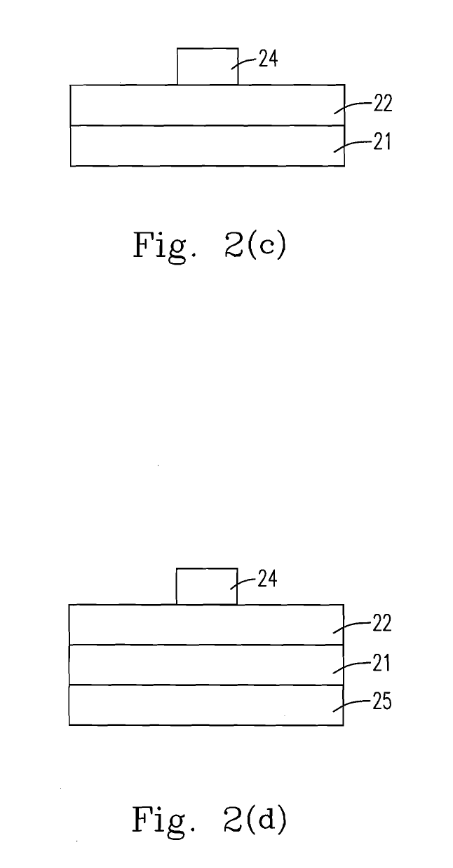

Please refer to FIGS. 2(a)-2(d), which are schematic diagrams showing the method of using the III-V semiconductor material as the gate electrode according to a preferred embodiment of the present invention. Firstly, an N-type silicon substrate 21 is provided, and an SiO₂ oxidation layer 22 with the thickness of 30 nm is formed on the N-type silicon substrate 21, as shown in FIG. 2(a). Then, a P-type heavily-doped (P⁺) poly-crystalline InAs with the thickness of 1 um 23 is formed on the SiO₂ oxidation layer 22 by a molecular beam epitaxy (NBE) system, as shown in FIG. 2(b), wherein the doping concentration of the P-type heavily-doped (P⁺) poly-crystalline InAs 23 is 1×10¹⁹ cm⁻³.

After the formation of the P-type heavily-doped (P⁺) poly-crystalline InAs 23, a gate 24 is defined by photolithography and etching, as shown in FIG. 2(c). Finally, an aluminum film is plated on the bottom side of the N-type silicon substrate 21 to form an ohmic-contact electrode 25, as shown in FIG. 2(d), thereby completing the fabrication of a MOS capacitor. Moreover, under the same fabrication conditions, a conventional capacitor with the gate electrode of aluminum is fabricated for comparison.

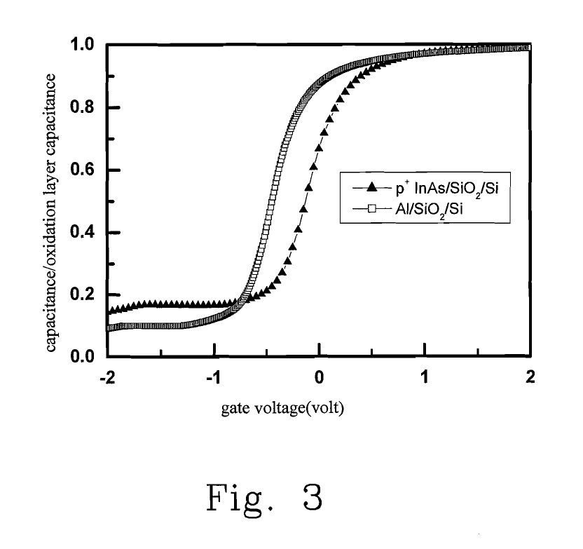

Please refer to FIG. 3, which is a diagram showing the capacitance-voltage characteristic according to a preferred embodiment of the present invention. As shown in FIG. 3, compared to the capacitance element which uses aluminum as the gate electrode, the flat-band voltage of the capacitance element which uses the P-type heavily-doped (P⁺) poly-crystalline InAs 23 as the gate electrode 24 moves toward the positive bias direction. According to the semiconductor element physics, if the work function of the gate becomes larger, the flat-band voltage thereof moves further toward the positive bias direction, and the threshold voltage also moves toward the positive bias direction. This embodiment shows that the work function of the P-type heavily-doped (P⁺) poly-crystalline InAs 23 is larger than that of the aluminum, wherein the electron affinity of the P-type heavily-doped (P⁺) poly-crystalline InAs 23 is 4.9 eV, while the electron affinity of the aluminum is 4.1 eV This embodiment uses the P-type heavily-doped (P⁺) poly-crystalline InAs 23 to serve as the gate electrode 24, which enables the work function thereof to be close to the silicon valence band. Furthermore, the work function can be slightly adjusted by changing the doping concentration arbitrarily, so that the adjustment of the threshold voltage can be optimized. These characteristics are quite beneficial for the performance of the field effect transistor.

To sum up, a method of using the III-V semiconductor material as the gate electrode is provided in order to adjust the threshold voltage. The III-V semiconductor material is formed on the gate dielectric layer. The work function of the III-V semiconductor material can be changed by doping it as P-type or N-type and changing the doping concentration thereof arbitrarily. Hence, the threshold voltage thereof can be optimized, thereby enhancing the performance of the filed effect transistor. Therefore, the present invention effectively solves the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method of using an III-V semiconductor material as a gate electrode, comprising steps of:
providing a substrate;
forming a gate dielectric layer on the substrate; and
forming the III-V semiconductor material on the gate dielectric layer.

2. A method as claimed in claim 1, wherein the substrate is a silicon substrate.

3. A method as claimed in claim 2, wherein the silicon substrate is one of a silicon {100} substrate, a silicon {110} substrate and a silicon {111} substrate.

4. A method as claimed in claim 2, wherein the silicon substrate is doped as one of a P-type substrate and an N-type substrate.

5. A method as claimed in claim 2, wherein the silicon substrate is one of a wafer and a die.

6. A method as claimed in claim 1, wherein a size and a shape of the silicon substrate are changeable.

7. A method as claimed in claim 1, wherein the gate dielectric layer is made of a dielectric layer material with a dielectric constant larger than 3.

8. A method as claimed in claim 7, wherein the dielectric layer material is selected from a group consisting of an SiO₂, an Si₃N₄ and an HfO₂.

9. A method as claimed in claim 1, wherein the III-V semiconductor material is formed by one selected from a group consisting of a molecular beam epitaxy, a plasma-enhanced chemical vapor deposition and a chemical vapor deposition.

10. A method as claimed in claim 1, wherein the III-V semiconductor material is one selected from a group consisting of a poly-crystalline material, a single-crystalline material and an amorphous material.

11. A method as claimed in claim 1, wherein the III-V semiconductor material is a compound composed of at least one of an Al, a Ga and an In in Group III of a periodic table and at least one of an N, a P, an As and an Sb in Group V of the periodic table.

12. A method as claimed in claim 11, wherein the compound is one selected from a group consisting of an InAs, an Inp, a GaSb, a GaAs, a Gap, a GaN, an AlxGal-xAs and a GaxInl-xAs.

13. A method as claimed in claim 1, wherein the III-V semiconductor material is doped as one of a P-type material and an N-type material.

14. A method as claimed in claim 13, wherein a doping concentration of the III-V semiconductor material is adjustable.

15. A gate electrode, comprising:
an III-V semiconductor material.

16. A gate electrode as claimed in claim 15, wherein the III-V semiconductor material is formed by one selected from a group consisting of a molecular beam epitaxy, a plasma-enhanced chemical vapor deposition and a chemical vapor deposition.

17. A gate electrode as claimed in claim 15, wherein the III-V semiconductor material is one selected from a group consisting of a poly-crystalline material, a single-crystalline material and an amorphous material.

18. A gate electrode as claimed in claim 15, wherein the III-V semiconductor material is a compound composed of at least one of an Al, a Ga and an In in Group III of a periodic table and at least one of an N, a P, an As and an Sb in Group V of the periodic table.

19. A gate electrode as claimed in claim 18, wherein the compound is one selected from a group consisting of an InAs, an Inp, a GaSb, a GaAs, a Gap, a GaN, an AlxGal-xAs and a GaxInl-xAs.

20. A gate electrode as claimed in claim 15, wherein the III-V semiconductor material is doped as one of a P-type material and an N-type material.

21. A gate electrode as claimed in claim 20, wherein a doping concentration of the III-V semiconductor material is adjustable.
